(19) United States
(12) Patent Application Publication
(10) Pub. No.: US 2015/0137179 A1
(43) Pub. Date: May 21, 2015

(54) POWER DEVICE

(71) Applicants: HUGA OPTOTECH INC., TAICHUNG (TW); EPISTAR CORPORATION, HSINCHU (TW)

(72) Inventors: Ya-Yu YANG, Taichung (TW); Heng-Kuang LIN, Taichung (TW)

(73) Assignees: HUGA OPTOTECH INC., TAICHUNG (TW); EPISTAR CORPORATION, HSINCHU (TW)

(21) Appl. No.: 14/084,084

(22) Filed: Nov. 19, 2013

(51) Int. Cl. H01L 29/205; H01L 29/778; H01L 29/20

(52) U.S. Cl. CPC H01L 29/205; H01L 29/2003; H01L 29/778
USPC 257/190

(57) ABSTRACT

A power device disclosed herein comprises a substrate, a first semiconductor layer formed on the substrate, a second semiconductor layer formed on the first semiconductor layer and comprising a first element of group III, a third semiconductor layer formed on the second semiconductor layer and a plurality of first interlayers formed in the third semiconductor layer and comprising a second element of III group. The first element of III group and the second element of III group are the same. The second semiconductor layer and the plurality of first interlayers are doped with carbon.

### TECHNICAL FIELD

This present application relates to a power device, and more particularly to a power device having a grading interlayer doped with carbon.

### BACKGROUND OF THE DISCLOSURE

Recently, group III nitride semiconductor such as gallium nitride (GaN) develops rapidly for the high power devices because of its wider band gap, high breakdown field strength, and high electron saturation velocity. In a heterostructure of aluminum gallium nitride (AlGaN)/gallium nitride (GaN) formed on a substrate, two-dimensional electron gas (2DEG) is generated at a heterointerface due to spontaneous polarization and piezoelectric polarization. Particular attention has been drawn to Schottky barrier diodes (SBDs) and field effect transistors (FETs) using a high concentration 2DEG as a carrier.

If GaN-based nitride semiconductors are formed on a hetero-substrate, since the lattice constant and the coefficient of thermal expansion of the substrate are different from those of the nitride semiconductors, problems such as bowing and cracks are likely to occur.

### SUMMARY OF THE DISCLOSURE

A power device comprises a substrate, a first semiconductor layer formed on the substrate, a second semiconductor layer formed on the first semiconductor layer and comprising a first element of group III, a third semiconductor layer formed on the second semiconductor layer and a plurality of first interlayers formed in the third semiconductor layer and comprising a second element of III group. The first element of III group and the second element of III group are the same. The second semiconductor layer and the plurality of first interlayers are doped with carbon.

A power device comprises a substrate, a first semiconductor layer formed on the substrate, a second semiconductor layer formed on the first semiconductor layer, a third semiconductor layer formed on the second semiconductor layer, a plurality of first interlayers formed in the third semiconductor layer and comprising a first lattice constant, and a plurality of second interlayers formed in the third semiconductor layer and comprising a second lattice constant. The first lattice constant is less than the second lattice constant

### BRIEF DESCRIPTION OF THE DRAWINGS

FIG. 1 shows a cross-section of a power device in accordance with a first embodiment of the present disclosure.

FIGS. 2A-2L show a cross-section of a fabricating method of a power device in accordance with the first embodiment of the present disclosure.

FIG. 3 shows a cross-section of a power device in accordance with a second embodiment of the present disclosure.

FIG. 4 shows a cross-section of a power device in accordance with a third embodiment of the present disclosure.

### DETAILED DESCRIPTION OF THE PREFERRED EMBODIMENTS

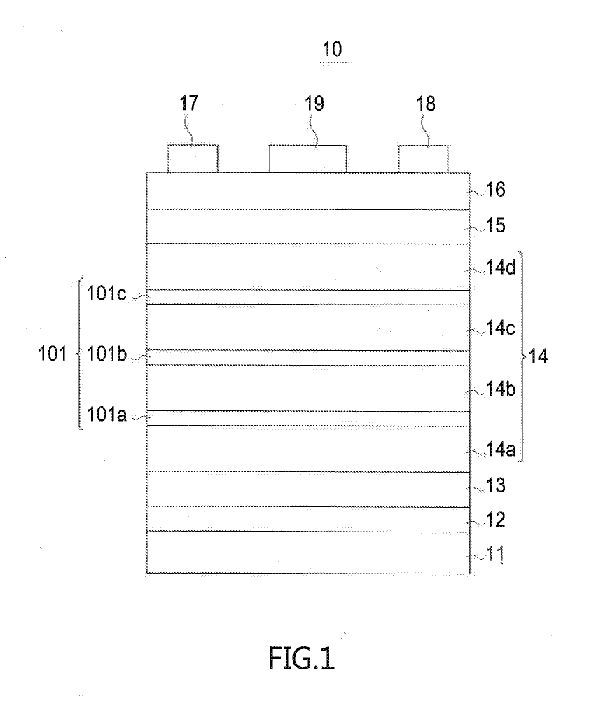

FIG. 1 shows a power device in accordance with a first embodiment of the present disclosure. The power device 10 comprises a substrate 11, a first semiconductor layer 12 formed on the substrate 11, a second semiconductor layer 13 formed on the first semiconductor 12, a third semiconductor layer 14 formed on the second semiconductor layer 13, and a plurality of first interlayers 101 formed in the third semiconductor layer 14, wherein the third semiconductor layer 14 is separated into a plurality of sublayers 14a˜14d by the first interlayers 101a˜101c.

The substrate 11 may be made of a material suitable for growing nitride semiconductor, such as Si, SiC, GaN or sapphire. The first semiconductor layer 12 having a thickness of 150 nm can be a nucleation layer and comprises a first element of group III. The second semiconductor layer 13 having a thickness range between 700˜800 nm can be a grading layer and comprises a second element of group III which is same as the first element, such as Al. The third semiconductor layer 14 having a thickness of 4 μm can be a buffer layer.

The first interlayers 101a˜101c can also be buffer layers used to adjust the stress and coefficient of thermal expansion of the substrate 11 and increase the thickness of the buffer layer. The first interlayers 101a˜101c may comprise MN or AlGaN, and every first interlayer has a thickness range between 1 nm˜100 nm, wherein the thickness of the first interlayer is preferably 20 nm.

The second semiconductor layer 13, third semiconductor layer 14 or/and the first interlayers 101a˜101c may be doped with carbon to prevent the leakage current of the substrate 11, increase the resistance of buffer layer and raise the breakdown voltage. A range of the doping concentration may be between 1×10^{17 to} 1×10²⁰ cm⁻³ and a doping type comprises grading type, step type and contact type.

The power device 10 further comprises a channel layer 15, a supplying layer 16, a source electrode 17, a drain electrode 18, and a gate electrode 19. The channel layer 15 having a thickness range between 50˜300 nm is formed on the third semiconductor layer 14. The supplying layer 16 having a thickness range between 20˜30 nm is formed on the channel layer 15, wherein the piezoelectric polarization and the spontaneous polarization occur at an interface between the channel layer 15 and the supplying layer 16 by the different lattice constant, and then a two dimensional electron gas (2DEG) can be generated by heterostructural interface of channel layer 15 and supplying layer 16.

The gate electrode 17 is formed on the supplying layer 16 and in schottky contact with the supplying layer 16. The source electrode 18 and the drain electrode 19 are formed in both lateral regions of the gate electrode 17 and in ohmic contact with the supplying layer 16.

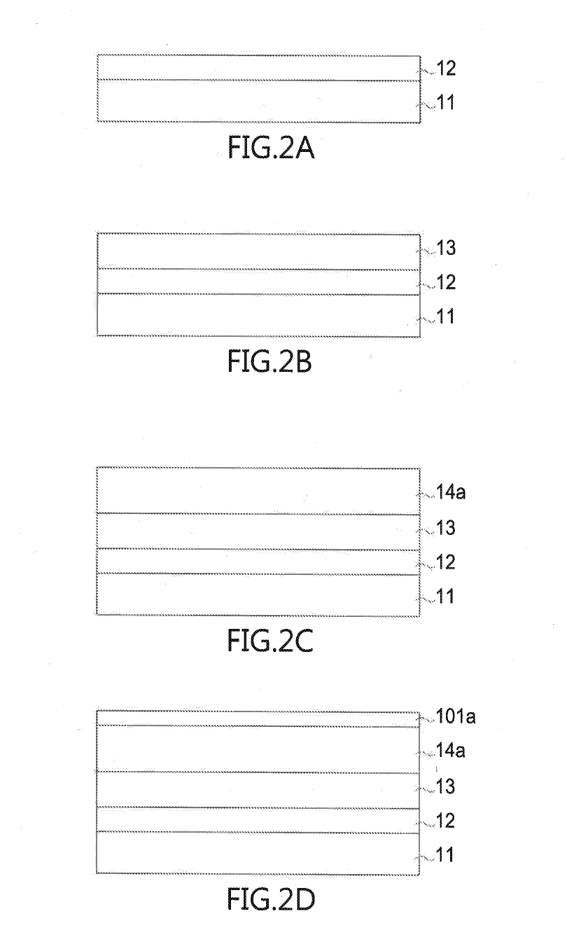

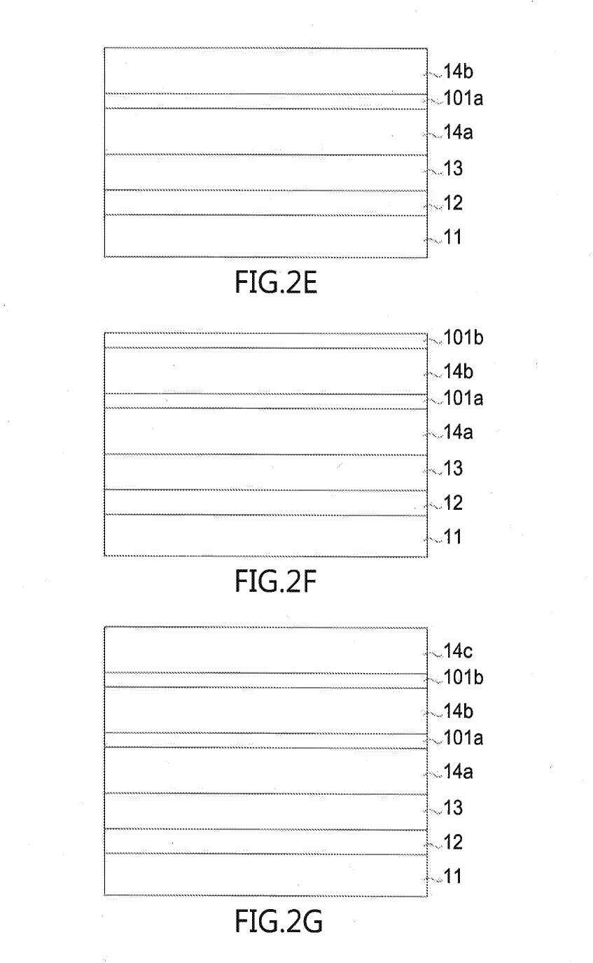

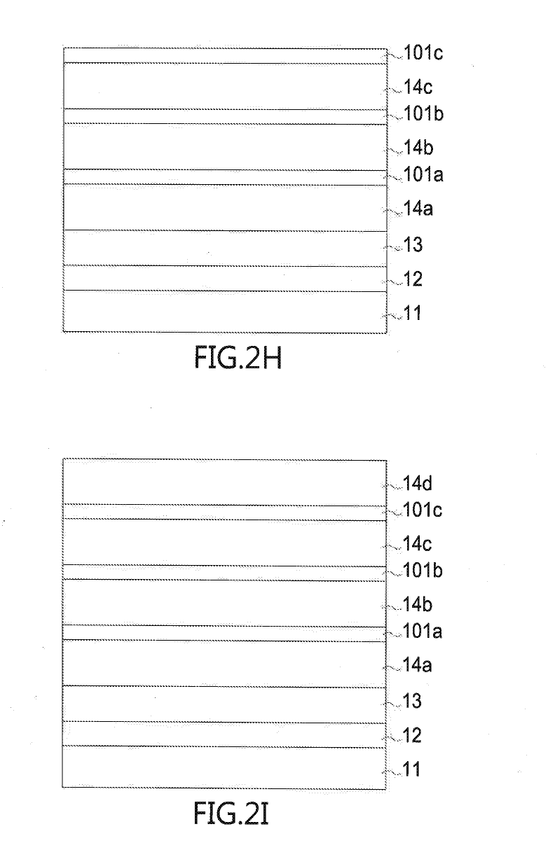

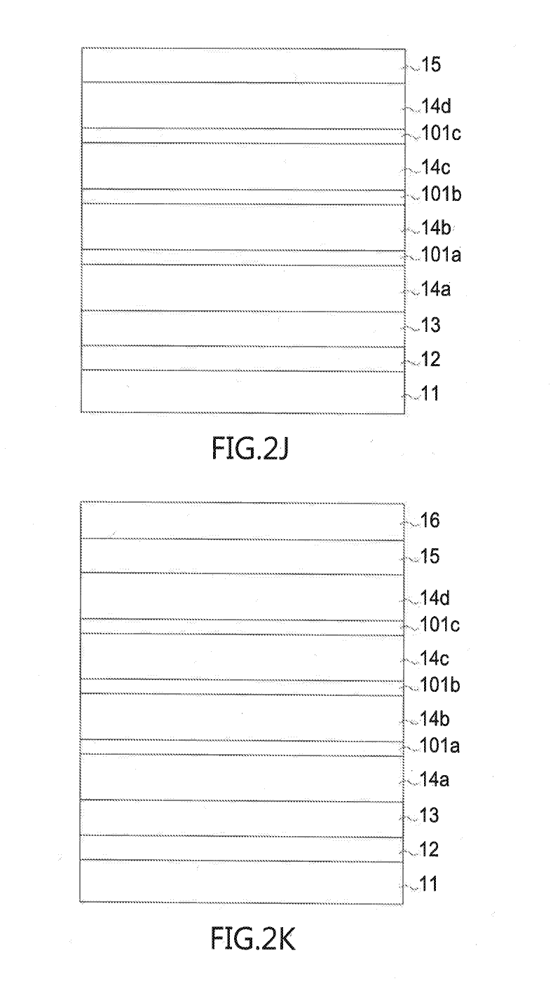

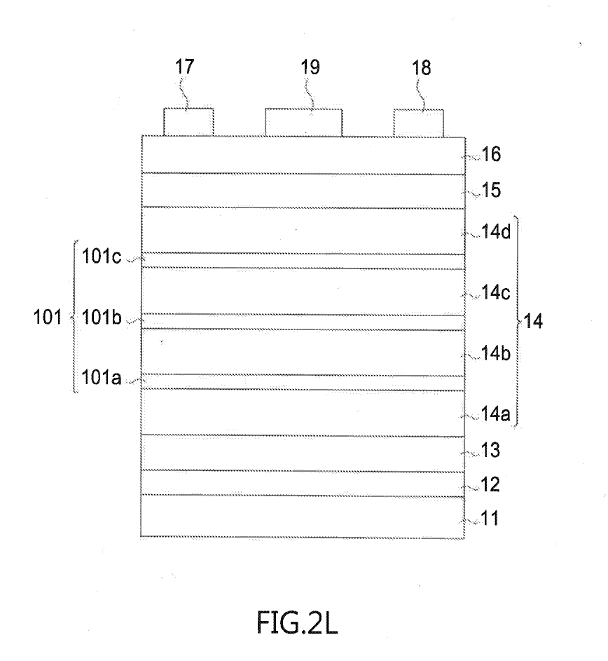

FIGS. 2A-2K show a fabricating method of a power device in accordance with the first embodiment of the present disclosure. The first semiconductor layer 12 having a thickness of 150 nm and made of AlN is grown on the (111) plane of the substrate 11 made of Si, as shown in FIG. 2A. The second semiconductor layer 13 having a thickness of 700 nm, made of AlGaN and doped with 1×10¹⁸ cm⁻³ of carbon is grown on the first semiconductor layer 12, wherein the second semiconductor layer 13 is a grading layer with a different content of Al which is decreased in a direction away from the substrate 11, as shown in FIG. 2B. The sublayer 14a of the third semiconductor layer 14 having a thickness of 1 μm, made of GaN and doped with 5×10¹⁹ cm⁻³ of carbon is grown on the second semiconductor layer 13, as shown in FIG. 2C. The first interlayer 101a having a thickness of 20 nm, made of AlN and doped with 1×10¹⁸ cm⁻³ of carbon is grown on the sublayer 14a, as shown in FIG. 2D. The sublayer 14b of the third semiconductor layer 14 having a thickness of 1 μm, made of GaN and doped with 5×10¹⁹ cm⁻³ of carbon is grown on the first interlayer 101a, as shown in FIG. 2E. The first interlayer 101b having a thickness of 20 nm, made of AlN and doped with 1×10¹⁸ cm⁻³ of carbon is grown on the sublayer 14b, as shown in FIG. 2F. The sublayer 14c of the third semiconductor layer 14 having a thickness of 1 μm, made of GaN and doped with 5×10¹⁹ cm⁻³ of carbon is grown on the first interlayer 101b, as shown in FIG. 2G. The first interlayer 101c having a thickness of 20 nm, made of AlN and doped with 1×10¹⁸ cm⁻³ of carbon is grown on the sublayer 14c as shown in FIG. 2H. The sublayer 14d of the third semiconductor layer 14 having a thickness of 1 μm, made of GaN and doped with 5×10¹⁹ cm⁻³ of carbon is grown on the first interlayer 101c, as shown in FIG. 21. The process of growing the third semiconductor layer 14 and the first interlayers 101, firstly, TMGa, NH₃ and CBr₄ (or CCl₄) are injected to grow the sublayer 14a, wherein a mole content ratio of N and Ga is between 400˜1000. Secondly, TMAl, NH₃ and CBr₄ (or CCl₄) are injected to grow the first interlayer 101a, wherein a mole content ratio of N and Al is between 500˜4000. The first step and the second step are repeated three times to from the sublayer 104a˜104c and first interlayer 101a˜101c. Finally, TMGa, NH₃ and CBr₄ (or CCl₄) are injected to grow the sublayer 14d.

Then, the channel layer 15 made of undoped GaN and having a thickness of 100 nm is grown on the sublayer 14d, as shown in FIG. 2J. The supplying layer 16 made of undoped AlGaN and having a thickness of 25 nm is grown on the channel layer 15, as shown in FIG. 2K. The above descriptions of manufacturing steps are performed by metal organic chemical vapor deposition (MOCVD) at a range of pressure between 30˜200 mbar and in a range of temperature between 900˜1100° C. The term “undoped” herein means that no impurities are intentionally introduced.

Subsequently, as shown in FIG. 2L, a stack of Ti/Al/Ti/Au with a thickness of 500 nm are formed on the supplying layer 16, and then a heating process is performed at 900° C. in nitrogen atmosphere, thereby forming the source electrode 17 and the drain electrode 18. At last, a gate electrode 19 is a stack of Ni/Au with a thickness of 500 nm and formed on the supplying layer 16.

Although the power device and the method of manufacturing the power device of the first embodiment have been described above, the present disclosure is not limited to the first embodiment. For example, the number of the first interlayers is not limited to the first embodiment, more than three first interlayers can be formed in the third semiconductor layer 14.

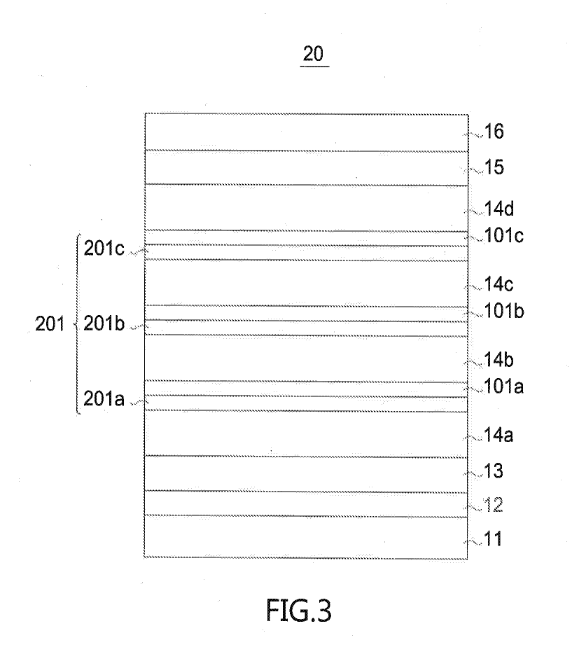

FIG. 3 shows a power device in accordance with a second embodiment of the present disclosure. In the second embodiment, the power device structure of the second embodiment is similar to that of the first embodiment, except that the power device 20 further comprises a plurality of second interlayers 201, and the method of manufacturing process is without carbon doping.

The second interlayers 201a˜201c are formed in the third semiconductor layer 14 and can also be buffer layers used to adjust the stress and coefficient of thermal expansion of the substrate 11 and increase the thickness of the buffer layer. The second interlayers 201a˜201c may comprise AlGaN or AlInGaN, and every second interlayer has a thickness range between 1 nm˜100 nm, wherein the thickness of the second interlayer is preferably 20 nm. In the second embodiment, the first interlayers 101a˜101c comprise a first lattice constant and the second interlayers 201a˜201c comprise a second lattice constant, wherein the first lattice constant is smaller than the second lattice constant.

As shown in FIG. 3, the first interlayers 101a˜101c and the second interlayers 201a˜201c are adjacent to each other respectively. The second interlayers 201a˜201c are disposed between the sublayer 14a˜14c and the first interlayers 101a˜101c respectively and below the first interlayers 101a˜101c respectively.

Furthermore, the plurality of second interlayers 201 comprises a third element of III group which is same as the second element of the first interlayers 101, such as Al. A variance type of a content of the third element comprises grading type, step type, and contact type. In the second embodiment, a content of Al of the second interlayers 201a˜201c is decreased in a direction away from the adjacent first interlayers 101a˜101c, respectively. For example, a content of Al of the second interlayer 201a is decreased in a direction away from the adjacent first interlayer 101a.

In other words, a variance type of the second lattice constant comprises grading type, step type, and contact type. The second lattice constant of the second interlayers 201a˜201c is increased in a direction away from the adjacent first interlayers 101a˜101c, respectively.

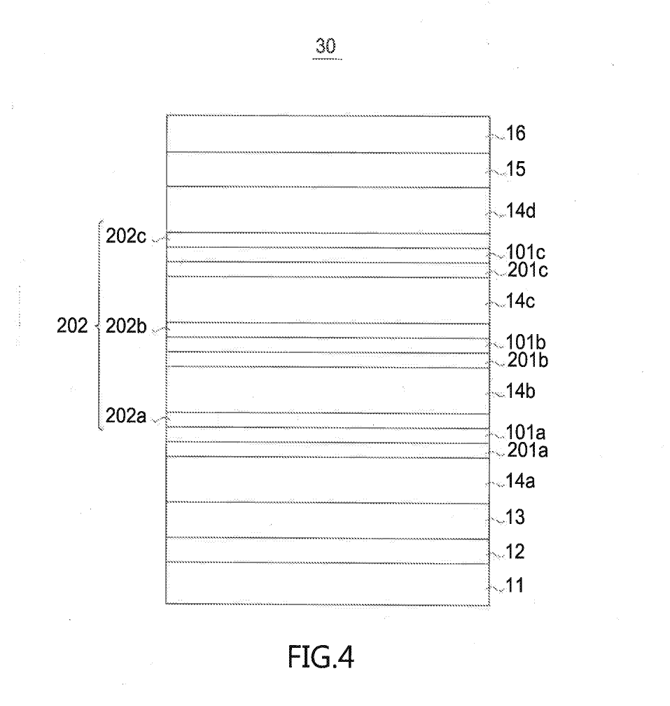

FIG. 4 shows a power device in accordance with a third embodiment of the present disclosure. In the third embodiment, the power device structure of the third embodiment is similar to that of the second embodiment, except that the power device 30 further comprises a plurality of second interlayers 202a˜202c are adjacent and above the first interlayers 101a˜101c. In the third embodiment, the first interlayers 101a˜101c are sandwiched between two of the second interlayers 201a˜201c and 202a˜202c respectively. A content of Al of the second interlayers 201a˜201c and 202a˜202c is decreased in a direction away from the adjacent first interlayers 101a˜101c, respectively. For example, a content of Al of the second interlayer 201a and 202a is decreased in a direction away from the adjacent first interlayer 101a.

In the fourth embodiment, the power device structure of the fourth embodiment is similar to that of the second embodiment, except that the second semiconductor layer 13, third semiconductor layer 14, the first interlayers 101a˜101C or/and the second interlayers 201a˜201c may be doped with carbon to prevent the leakage current of the substrate 11, increase the resistance of buffer layer, and raise the breakdown voltage. A range of the doping concentration may be between 1×10¹⁷ to 1×10²⁰ cm⁻³ and a doping type comprises grading type, step type, and contact type.

In the fifth embodiment, the power device structure of the fifth embodiment is similar to that of the third embodiment, except that the second semiconductor layer 13, third semiconductor layer 14, the first interlayers 101a˜101C or/and the second interlayers 201a˜201c, 202a˜202c may be doped with carbon. A range of the doping concentration may be between 1×10¹⁷ to 1×10²⁰ cm⁻³ and a doping type comprises grading type, step type and contact type.

Table 1 shows the experimental result of the comparable sample and samples A˜C in different carbon concentrations when the working voltage is 600V, wherein the leakage current is lower while the carbon concentration is higher, and the leakage current is over limit while the compared sample is un-doped. This obviously shows that the second semiconductor layer, the third semiconductor layer and interlayers doped with carbon is beneficial to reduce the leakage current.

Table 2 shows the experimental results of the comparable sample and samples A˜C in different thicknesses when the working current is 1 mA, wherein a thickness is a sum of a thickness from the first semiconductor layer to the supplying layer. The breakdown voltage is higher while the thickness is thicker. Thus, it is useful to increase thicknesses of GaN-based nitride semiconductors to raise the breakdown voltage.

It should be noted that the proposed various embodiments are not for the purpose to limit the scope of the disclosure. Any possible modifications without departing from the spirit of the disclosure may be made and should be covered by the disclosure.

TABLE 1

| Sample | Carbon Concentration | Leakage Current |
|---|---|---|
| Compared Sample | un-doped | breakdown |
| Sample A | ~1 × 1018 cm-3 | ~2 × 10-5 A |
| Sample B | ~5 × 1018 cm-3 | ~2 × 10-8 A |
| Sample C | ~1 × 1019 cm-3 | ~8 × 10-8 A |

TABLE 2

| Sample | Thickness | Breakdown Voltage |
|---|---|---|
| Compared Sample | 2 um | 800 V |
| Sample A | 5 um | 1200 V |
| Sample B | 6 um | 1500 V |
| Sample C | 8 um | 2500 V |

1. A power device, comprising:
a substrate;
a first semiconductor layer formed on the substrate;
a second semiconductor layer formed on the first semiconductor layer and comprising a first element of group III;
a third semiconductor layer formed on the second semiconductor layer; and
a plurality of first interlayers formed in the third semiconductor layer and comprising a second element of ITT group;
wherein the first element of III group and the second element of III group are the same;
wherein the second semiconductor layer and the plurality of first interlayers are doped with carbon.

2. The power device according to claim 1, wherein the third semiconductor layer is doped with carbon,

3. The power device according to claim 1, wherein the third semiconductor layer is separated into a plurality of sublayers by the plurality of first interlayers.

4. The power device according to claim 3, further comprising a plurality of second interlayers formed in the third semiconductor layer, wherein the plurality of second interlayers are doped with carbon.

5. The power device according to claim 4, wherein doping types of the second semiconductor layer, the plurality of first interlayers, the third semiconductor layer and the plurality of second interlayers comprise grading type, step type and constant type.

6. The power device according to claim 4, wherein a dopant concentration range of carbon in the second semiconductor layer, the plurality of first interlayers, the third semiconductor layer or the plurality of second interlayers is between 1×10¹⁷ to 1×10²⁰ cm⁻³.

7. The power device according to claim 4, wherein the plurality of first interlayers and the plurality of second interlayers are adjacent to each other respectively.

8. The power device according to claim wherein each of the second interlayers comprises a third element of III group and a content of the third element of III group is decreased in a direction away from the adjacent first interlayer.

9. The power device according to claim 8, wherein the third element and the second element are the same.

10. The power device according to claim 4, wherein the second interlayer comprises AlGaN or AlInGaN.

11. The power device according to claim 1, wherein the first interlayer comprises AlN or AlGaN.

12. A power device, comprising:
a substrate;
a first semiconductor layer formed on the substrate;
a second semiconductor layer formed on the first semiconductor layer;
a third semiconductor layer formed on the second semiconductor layer;
a plurality of first interlayers formed in the third semiconductor layer and comprising a first lattice constant; and
a plurality of second interlayers formed in the third semiconductor layer and comprising a second lattice constant;
wherein the first lattice constant is smaller than the second lattice constant.

13. The power device according to claim 12, wherein the third semiconductor layer is separated into a plurality of sublayers by the plurality of first interlayers.

14. The power device according to claim 13, wherein the plurality of second interlayers is disposed between the plurality of first interlayers and the plurality of sublayers respectively.

15. The power device according to claim 14, wherein the second lattice constant comprises a grading lattice constant increase in a direction away from the first interlayer.

16. The power device according to claim 13, wherein each of the first interlayers is sandwiched in between two of the second layers respectively.

17. The power device according to claim 16, wherein the second lattice constant of the plurality of second interlayers comprises a grading lattice constant increased in a direction away from the first interlayers.

18. The power device according to claim 12, wherein a thickness range of the first interlayers is between 1˜100 nm.

19. The power device according to claim 12, wherein a thickness range of the second interlayers is between 1˜100 nm.

20. The power device according to claim 12, wherein a variance type of the second lattice constant comprises grading type, step type, or constant type.
